(19) United States
(12) Patent Application Publication
(10) Pub. No.: US 2024/0266489 A1
(43) Pub. Date: Aug. 8, 2024

(54) DISPLAY DEVICE AND MANUFACTURING METHOD THEREOF

(71) Applicant: Samsung Display Co., LTD., Yongin-si (KR)

(72) Inventors: Yeon Hwa LEE, Yongin-si (KR); HYE JIN GWARK, Yongin-si (KR); Jae Ik KIM, Yongin-si (KR); HWI KIM, Yongin-si (KR); JUNGSUN PARK, Yongin-si (KR); DUCKJUNG LEE, Yongin-si (KR); Joon Gu LEE, Yongin-si (KR)

(73) Assignee: Samsung Display Co., LTD., Yongin-si (KR)

(21) Appl. No.: 18/522,563

(22) Filed: Nov. 29, 2023

(30) Foreign Application Priority Data
Feb. 8, 2023 (KR) 10-2023-0016853

(51) Int. Cl. H01L 33/62; H01L 25/075; H01L 33/56

(52) U.S. Cl. CPC H01L 33/62; H01L 25/0753; H01L 33/56; H01L 2933/005

(57) ABSTRACT

A display device according to an embodiment includes a display area and a non-display area, an external common voltage line formed in the non-display area, a common voltage line formed in the display area and connecting a portion and another portion of the external common voltage line, a plurality of pixels positioned in the display area and including a first electrode and an emission layer, and a second electrode positioned on the plurality of pixels. The common voltage line has a multi-layered structure including a first layer, a second layer, a third layer, and a reinforced layer. The reinforced layer is positioned between the second layer and the third layer, the first layer, the second layer, and the third layer include a metal, and the reinforced layer includes an inorganic material or an organic material.

### CROSS-REFERENCE TO RELATED APPLICATION(S)

This application claims priority to and the benefit of Korean Patent Application No. 10-2023-0016853 under 35 U.S.C. § 119, filed on Feb. 8, 2023, in the Korean Intellectual Property Office (KIPO), the entire contents of which are incorporated herein by reference.

### BACKGROUND

### 1. Technical Field

The disclosure relates to a display device and a manufacturing method.

### 2. Description of the Related Art

Recently, a light emitting display device such as a self-light emitting display device has attracted attention as a device for displaying an image.

The light emitting display device has a self-luminance characteristic and does not require a separate light source, unlike a liquid crystal display (LCD) device, and thus can have reduced thickness and weight. Further, the light emitting display device has high quality characteristics including low power consumption, high luminance, and a high reaction speed.

In general, the light emitting display device includes a substrate, multiple thin film transistors positioned on the substrate, multiple insulating layers disposed between wires constituting the thin film transistor, and a light emitting element connected to the thin film transistor.

The light-emitting element may include a first electrode, an emission layer, and a second electrode, and the second electrode may be positioned as a whole plate on the entire display device.

The above information disclosed in this Background section is only for enhancement of understanding of the background of the disclosure, and therefore it may contain information that does not form the prior art that is already known in this country to a person of ordinary skill in the art.

### SUMMARY

Embodiments are intended to provide a display device that prevents damage to wiring and prevents a voltage drop, and a manufacturing method thereof.

A display device according to an embodiment may include a display area and a non-display area, an external common voltage line formed in the non-display area, a common voltage line formed in the display area and connecting a portion and another portion of the external common voltage line, a plurality of pixels positioned in the display area and including a first electrode and an emission layer, and a second electrode positioned on the plurality of pixels. The common voltage line may have a multi-layered structure including a first layer, a second layer, a third layer, and a reinforced layer. The reinforced layer may be positioned between the second layer and the third layer. The first layer, the second layer, and the third layer may include a metal, and the reinforced layer may include an inorganic material or an organic material.

The reinforced layer may include an opening, and the second layer may directly contact the third layer in the opening.

The reinforced layer may include at least one of a silicon oxide (SiOₓ), a silicon nitride (SiNₓ), and a silicon oxynitride (SiOₓN_{y}).

The reinforced layer may include polyimide or an acrylic material.

A thickness of the reinforced layer may be in a range of about 20% to about 200% of a thickness of the third layer.

The thickness of the third layer may be in a range of about 200 Å to about 1000 Å.

The second layer may have an under-cut structure, and a width of the second layer may be smaller than a width of the third layer and a width of the reinforced layer.

The reinforced layer may include a first layer and a second layer, the first layer of the reinforced layer may include an inorganic material, and the second layer of the reinforced layer may include an organic material.

The reinforced layer may include multiple openings.

The second electrode may contact a side of the second electrode.

The first layer and the third layer may include a same material, and the first and third layers and the second layer may include different materials.

The first layer to the third layer may include different materials.

The display device may further include a source electrode and a drain electrode positioned in the display area. The common voltage line, the source electrode, and the drain electrode may be positioned on a same layer.

The emission layer and the second electrode may be sequentially positioned on the third layer of the common voltage line, and the third layer of the common voltage line may not directly contact the second electrode.

A manufacturing method of a display device according an embodiment of the disclosure may include forming a first layer, a second layer, and a reinforced layer on a substrate, forming a third layer on the reinforced layer, etching the third layer, the reinforced layer, the second layer, and the first layer, and additionally etching the second layer to form an under-cut structure in which a width of the second layer is smaller than a width of the third layer and a width of the reinforced layer. The first layer, the second layer, and the third layer may include a metal, and the reinforced layer may include an inorganic material or an organic material.

The manufacturing method may further include forming an opening in the reinforced layer. The second layer may directly contact the third layer in the opening.

The first layer, the second layer, and the third layer may include a metal, and the reinforced layer may include an inorganic material or an organic material.

A thickness of the reinforced layer may be in a range of about 20% to about 200% of a thickness of the third layer in a thickness direction of the substrate.

The reinforced layer may include at least one of a silicon oxide (SiOₓ), a silicon nitride (SiNₓ), a silicon oxynitride (SiOₓN_{y}), polyimide, and an acrylic material.

The reinforced layer may include a first layer and a second layer, the first layer of the reinforced layer may include an inorganic material, and the second layer of the reinforced layer may include an organic material.

The forming of the opening may include forming multiple openings in the reinforced layer.

According to embodiments, the display device preventing damage to the wiring and preventing a voltage drop, and the manufacturing method thereof, are provided.

### BRIEF DESCRIPTION OF THE DRAWINGS

FIG. 1 is a schematic plan view of a display device according to an embodiment.

FIG. 2 is a perspective view illustrating a configuration of a common voltage line positioned within a display area of a display device according to an embodiment.

FIG. 3 is a schematic cross-sectional view taken along line III-III′ of FIG. 2, illustrating a configuration of a common voltage line contacting a second electrode according to an embodiment.

FIG. 4 is a schematic cross-sectional view of a common voltage line illustrating a third layer deformed or damaged during a process.

FIG. 5 is a schematic cross-sectional view of a common voltage line illustrating a third layer deformed or damaged during a process.

FIG. 6 and FIG. 7 are views each showing an image in which a protruded part of a third layer of a common voltage line is damaged.

FIG. 8 is a schematic cross-sectional view of a common voltage line according to an embodiment.

FIG. 9 is a schematic cross-sectional view of a common voltage line according to an embodiment.

FIG. 10 is a schematic cross-sectional view of a common voltage line according to an embodiment.

FIG. 11 to FIG. 15 are schematic cross-sectional views illustrating a manufacturing process of a common voltage line according to an embodiment.

FIG. 16 to FIG. 20 are schematic cross-sectional views illustrating a manufacturing method of a common voltage line according to an embodiment.

FIG. 21 is a schematic cross-sectional view of a pixel of a display device according to an embodiment.

FIG. 22 is a schematic cross-sectional view taken along line III-III′ of FIG. 2, illustrating a configuration of a common voltage line contacting a second electrode according to an embodiment.

FIG. 23 is a schematic cross-sectional of a pixel of a display device according to an embodiment.

### DETAILED DESCRIPTION OF THE EMBODIMENTS

The embodiments will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clarify the disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are exaggerated.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Further, in the specification, the phrase “on a plane” or “in a plan view” means when an object portion is viewed from above, and the phrase “on a cross-section” or “in a cross-sectional view” means when a cross-section taken by vertically cutting an object portion is viewed from the side.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device according to an embodiment of the disclosure is described in detail with reference to accompanying drawings.

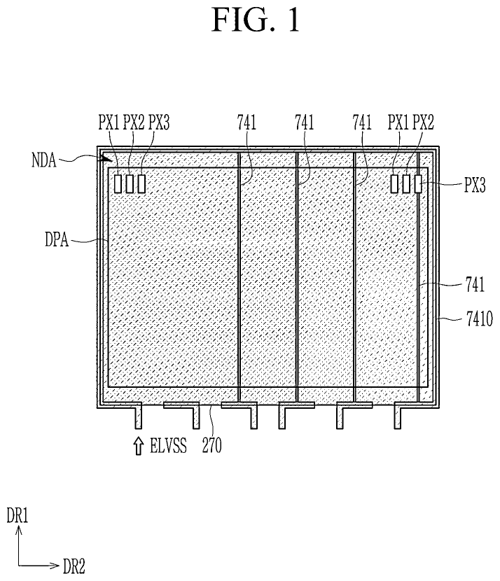

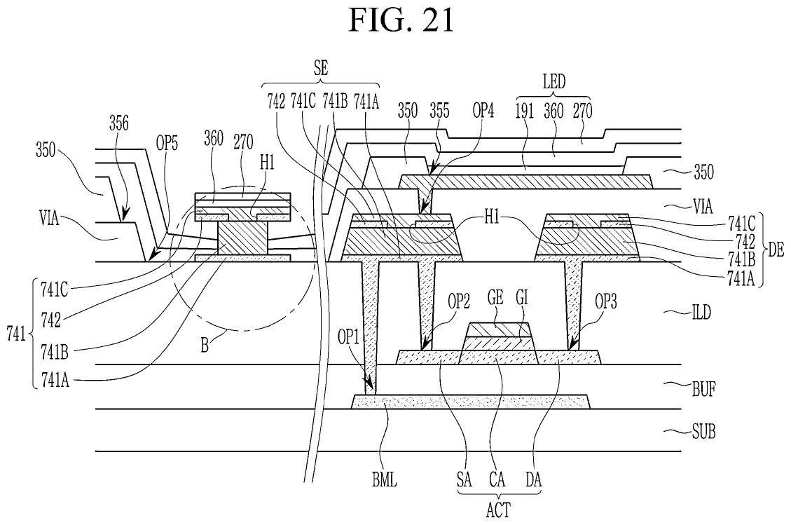

FIG. 1 is a schematic plan view of a display device according to an embodiment. Referring to FIG. 1, a display device according to an embodiment of the disclosure may include a display area DPA and a non-display area NDA. Multiple pixels PX1, PX2, and PX3 may be positioned in the display area. In FIG. 1, for better comprehension and ease of description, some pixels are only briefly shown. Each pixel PX may include a transistor and a light-emitting device connected thereto. The light-emitting device may include a first electrode, an emission layer, and a second electrode, and for better comprehension and ease of description, FIG. 1 shows the second electrode 270. The specific structure of the pixel PX and the light-emitting device in the display area will be described below with reference to FIG. 21.

In the non-display area NDA, an external common voltage line 7410 may be positioned. The external common voltage line 7410 may surround the display area DPA. External common voltage lines 7410 may be positioned apart from each other without being connected to each other on a side of the display area DPA. The external common voltage line 7410 may transmit a common voltage ELVSS to the second electrode 270 of the pixel PX.

A common voltage line 741 connected to the external common voltage line 7410 may be positioned in the display area DPA. The common voltage line 741 may connect the external common voltage lines 7410 to each other and extend in a first direction DR1. The common voltage line 741 and the source and drain electrodes of the display area DPA may be positioned on a same layer.

In case that the external common voltage line 7410 is connected to the common voltage line 741, the problem of the voltage decreasing during the transmission of the common voltage ELVSS may be solved. For example, in case that the external common voltage line 7410 is positioned to surround the edge of the display area DPA, a voltage reduction may occur while the common voltage ELVSS is transmitted along the external common voltage line 7410. However, in case that the common voltage line 741 positioned in the display area DPA is connected to the external common voltage line 7410, the voltage transmission path may be shortened, thereby preventing the common voltage from decreasing. The common voltage ELVSS may be transmitted to the second electrode 270.

Although not shown in FIG. 1, a driving voltage line transmitting a driving voltage may be further included. An external driving voltage line may be positioned in the non-display area, and a driving voltage line positioned in the display area may be connected to the external driving voltage line positioned in the non-display area. A driving voltage may be transmitted to each pixel of the display device through the driving voltage line.

Referring to FIG. 1, the display device may include the second electrode 270. The second electrode 270 may be positioned over the display area DPA and the non-display area NDA. The second electrode 270 may receive the common voltage ELVSS in contact with the external common voltage line 7410 in the non-display area NDA. In FIG. 1, in the region where the external common voltage line 7410 and the second electrode 270 are overlapped, the external common voltage line 7410 and the second electrode 270 may contact each other, and the common voltage ELVSS may be transmitted to the second electrode 270.

Also, the second electrode 270 may contact the common voltage line 741 in the display area DPA to transmit the common voltage ELVSS. Since the second electrode 270 receives the common voltage in the display area DPA and the non-display area NDA, the voltage drop may be minimized during the voltage transfer process and the common voltage may be readily transmitted to the second electrode 270.

FIG. 1 shows only a portion of the common voltage line 741, but the disclosure is not limited thereto, and the display device may include more than four common voltage lines 741 according to embodiments. As shown in FIG. 1, the common voltage line 741 may contact the second electrode 270 in only some pixels, but the disclosure is not limited thereto, and the common voltage line 741 may contact the second electrode 270 in each pixel. However, since a space is required in the display device to contact the common voltage line 741 and the second electrode 270, the common voltage line 741 and the second electrode 270 may be in contact with each other only in some pixels. For example, the common voltage line 741 may contact the second electrode 270 in every six pixels. However, the disclosure is not limited thereto.

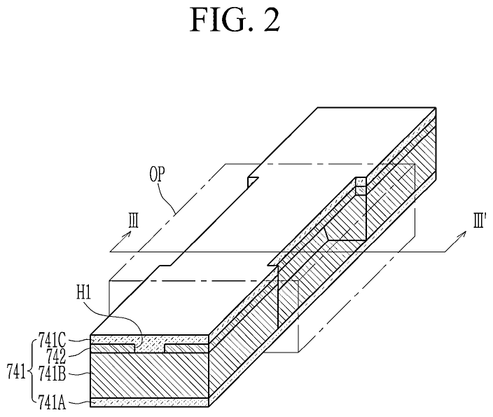

FIG. 2 is a perspective view illustrating a configuration of a common voltage line 741 positioned within a display area DPA of a display device according to an embodiment.

As shown in FIG. 2, the common voltage line 741 may have a 4-layered structure including a first layer 741A, a second layer 741B, a reinforced layer 742, and a third layer 741C. The first layer 741A, the second layer 741B, and the third layer 741C may include a metal. The reinforced layer 742 may be positioned between the second layer 741B and the third layer 741C, and may include an inorganic material or an organic material. The reinforced layer 742 may include an opening H1, and the second layer 741B and the third layer 741C may be in contact with each other in the opening H1. The common voltage line 741 according to an embodiment may prevent a damage by positioning the flexible reinforced layer 742 between the second layer 741B and the third layer 741C. The specific stacked structure will be described below.

An insulating layer may be positioned on the common voltage line 741 in the laminated structure of the display device, and an opening OP may be formed in the insulating layer for the contact between the common voltage line 741 and the second electrode 270. FIG. 2 shows the part where the opening OP is formed by a dotted line. In the formation process of the opening OP, the common voltage line 741 may be etched. Accordingly, in the region where the opening OP is formed, the common voltage line 741 may not be covered by the insulating layer and may be exposed, and may be in contact with the second electrode 270.

The common voltage line 741 may include the first layer 741A, the second layer 741B, and the third layer 741C including different materials, and may include the reinforced layer between the second layer 741B and the third layer 741C. The etching characteristics of the first layer 741A, the second layer 741B, and the third layer 741C may be different. For example, the second layer 741B may be etched more readily than other layers, and the common voltage line 741 and the second electrode 270 may be in contact in the second layer 741B.

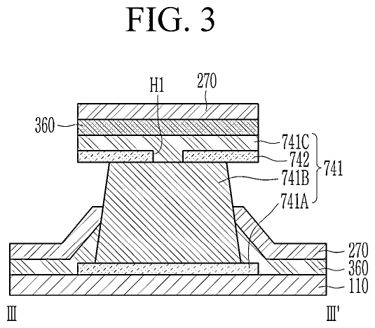

FIG. 3 is a schematic cross-sectional view taken along line III-III′ of FIG. 2 illustrating a configuration of the common voltage line 741 contacting the second electrode 270 according to an embodiment. As shown in FIG. 3, the common voltage line 741 may have an under-cut structure in which the second layer 741B is more etched than other layers.

In FIG. 3, an organic layer 360 may be positioned between the upper surface of the common voltage line 741 and the second electrode 270. The organic layer 360 may be an emission layer. On the manufacturing process, since the organic layer 360 is positioned between the second electrode 270 and the common voltage line 741, it may be difficult for the second electrode 270 to contact (e.g., directly contact) the upper surface of the common voltage line 741, for example, the upper surface of the third layer 741C. In order for the second electrode 270 to contact (e.g., directly contact) the upper surface of the common voltage line 741, a process using a separate mask for removing the organic layer 360 may be required, which reduces a process efficiency.

Accordingly, as shown in FIG. 3, the second electrode 270 may contact a side of the common voltage line 741. For this purpose, the common voltage line 741 may have an under-cut structure in which the second layer 741B is more etched than other layers.

Since the third layer 741C has the protruded under-cut structure, the protruded part may be deformed or damaged during subsequent processes.

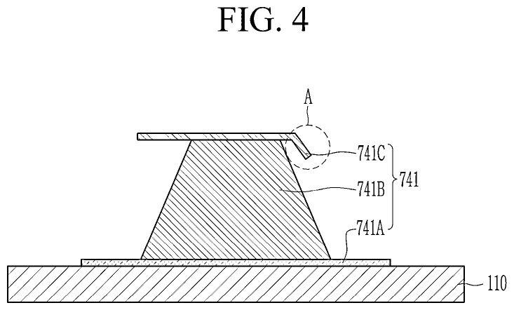

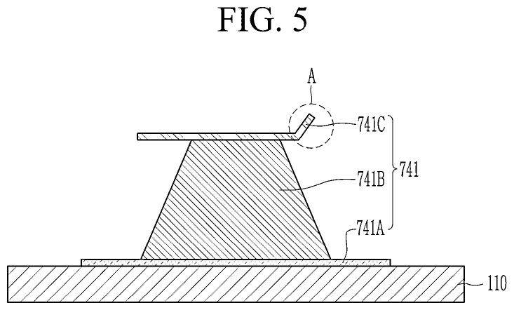

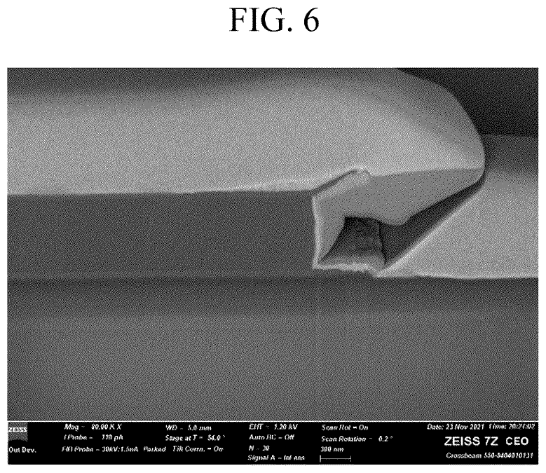

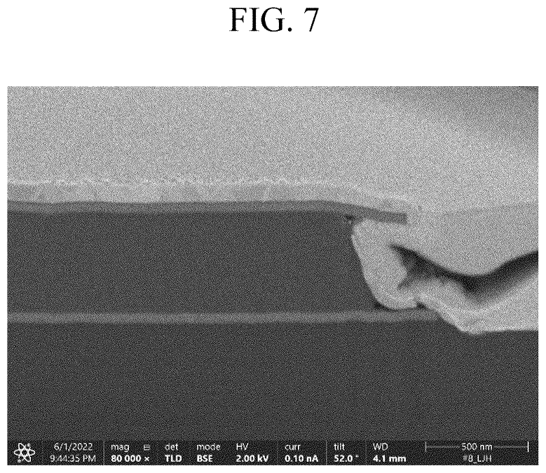

FIG. 4 and FIG. 5 are schematic cross-sectional views of a common voltage line illustrating a third layer deformed or damaged during a process. As shown by A in FIG. 4 and FIG. 5, the protruded part of the third layer 741C of the common voltage line 741 may be not supported by a lower structure and may be bent up or down during the process. FIG. 6 and FIG. 7 are views each showing an image in which a protruded part of a third layer 741C of a common voltage line 741 is damaged. It may be confirmed that the protruded part is bent upward in FIG. 6 and the protruded part is bent downward in FIG. 7.

However, a damage to the third layer 741C of the common voltage line 741 may be prevented by positioning the flexible reinforced layer 742 between the second layer 741B and the third layer 741C.

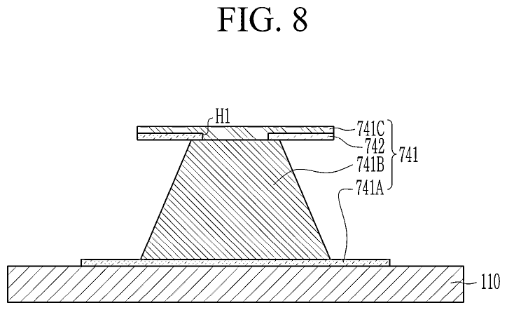

FIG. 8 is a schematic cross-sectional view of a common voltage line according to an embodiment. Referring to FIG. 8, the common voltage line 741 according to an embodiment may have a four-layered structure including the first layer 741A, the second layer 741B, the reinforced layer 742, and the third layer 741C. The first layer 741A, the second layer 741B, and the third layer 741C may include a metal. The reinforced layer 742 may be positioned between the second layer 741B and the third layer 741C and include a material that is more flexible than metal. For example, the reinforced layer 742 may include an inorganic material or an organic material. For example, the reinforced layer 742 may include at least one of a silicon oxide (SiOₓ), a silicon nitride (SiNₓ), and a silicon oxynitride (SiOₓN_{y}). For example, the reinforced layer 742 may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer. For example, the reinforced layer 742 may include polyimide or an acrylic material. In FIG. 8 shows that the reinforced layer 742 has a single layer, but the disclosure is not limited thereto, and according to an embodiment, the reinforced layer 742 may have a multi-layered structure.

Referring to FIG. 8, the reinforced layer 742 may include an opening H1. In the opening H1, the reinforced layer 742 may be removed, and the third layer 741C and the second layer 741B may contact each other. For example, since the reinforced layer 742 includes an inorganic material or an organic material and is not a conductive layer, the third layer 741C and the second layer 741B may contact each other and electrically connected in the opening H1. In FIG. 8, one opening H1 is shown, but the disclosure is not limited thereto, and the reinforce layer 742 may include more than one opening H1 according to an embodiment.

In an embodiment, the first layer 741A, the second layer 741B, and the third layer 741C may include at least one of Al, Cu, Ti, and alloys thereof. The first and third layers 741A and 741C and the second layer 741B may include different materials. The second layer 741B may include a material that is more readily etched than the first layer 741A and the third layer 741C. The first layer 741A and the third layer 741C may include a same material, and the first and third layers 741A and 741C and the second layer 741B may include different materials.

The thickness of the reinforced layer 742 may be in a range of about 20% to about 200% of the thickness of the third layer 741C in a thickness direction of the common voltage line 741. In case that the thickness of the reinforced layer 742 is thinner than 20% of the thickness of the third layer 741C, the reinforced layer 742 may not sufficiently support the third layer 741C, and the third layer 741C may be damaged. In case that the thickness of the reinforced layer 742 is thicker than 200% of the thickness of the third layer 741C, a residual film may remain during the formation process of the opening H1, and the third layer 741C and the second layer 741B may not be able to stably contact, and the process time of the formation process of the opening H1 may be longer. In an embodiment, the thickness of the third layer 741C may be in a range of about 200 Å to about 1000 Å in the thickness direction of the common voltage line 741.

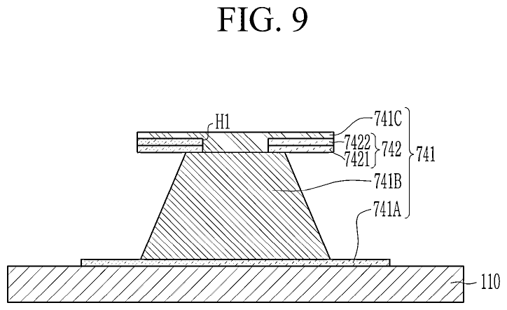

FIG. 9 is a schematic cross-sectional view of a common voltage line according to an embodiment. The common voltage line 741 of FIG. 9 is the same as that of the embodiment of FIG. 8 except that the reinforced layer 742 includes a first layer 7421 and a second layer 7422. The detailed description for the same constituent elements is omitted. In an embodiment, the reinforced layer may include a first layer 7421 and a second layer 7422. In an embodiment, the first layer 7421 may include an inorganic material, and the second layer 7422 may include an organic material. In another embodiment, the first layer 7421 may include an organic material, and the second layer 7422 may include an inorganic material. The inorganic material may be at least one selected from a silicon oxide (SiOₓ), a silicon nitride (SiNₓ), and a silicon oxynitride (SiOₓN_{y}). The organic material may be one or more selected from a general purpose polymer such as poly(methyl methacrylate) (PMMA) or polystyrene (PS), a polymer derivative having a phenolic group, an acryl-based polymer, an imide polymer, polyimide, and a siloxane polymer. For example, the organic material may be polyimide or an acrylic material.

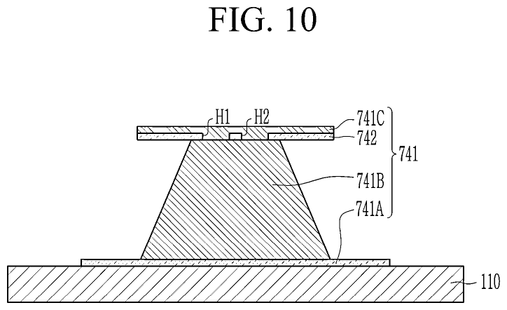

FIG. 10 is a schematic cross-sectional view of a common voltage line according to an embodiment. The common voltage line 741 of FIG. 10 is the same as that of the embodiment of FIG. 8 except that the reinforced layer 742 includes a first opening H1 and a second opening H2. The detailed description for the same constituent elements is omitted. Referring to FIG. 10, the reinforced layer according to an embodiment may include multiple openings.

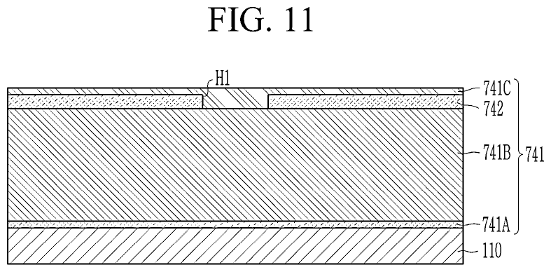

A manufacturing method of the common voltage line according to an embodiment is described with reference to accompanying drawings. FIG. 11 to FIG. 15 are schematic cross-sectional views illustrating a manufacturing process of a common voltage line according to an embodiment.

Referring to FIG. 11, a first layer 741A, a second layer 742B, a reinforced layer 742, and a third layer 741C may be sequentially stacked on a substrate 110. The reinforced layer 742 may include an opening H1, and the third layer 741C and the second layer 741B may be in contact (e.g., direct contact) in the opening H1. The reinforced layer 742 may include an inorganic material or an organic material. For example, the reinforced layer 742 may include at least one of a silicon oxide (SiOₓ), a silicon nitride (SiNₓ), and a silicon oxynitride (SiOₓN_{y}). For example, the reinforced layer 742 may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer. For example, the reinforced layer 742 may include polyimide or an acrylic material. The first layer 741A, the second layer 741B, and the third layer 741C may include at least one of Al, Cu, Ti, and alloys thereof. In an embodiment, the first layer 741A and the third layer 741C may include Ti, and the second layer 741B may include Al. The thickness of the reinforced layer 742 may be in a range of about 20% to about 200% of the thickness of the third layer 741C.

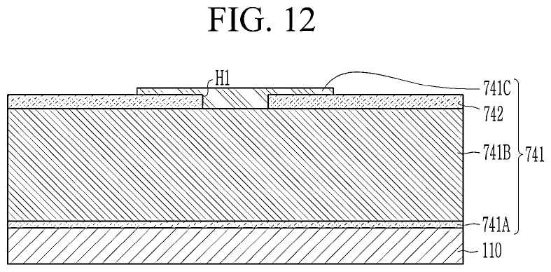

Referring to FIG. 12, the third layer 741C may be etched.

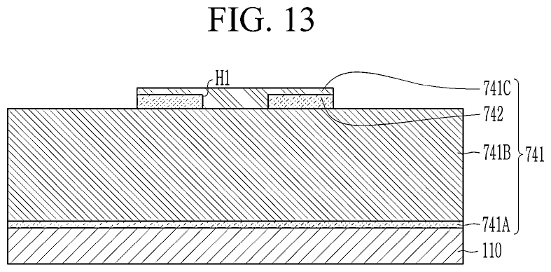

Referring to FIG. 13, the reinforced layer 742 may be etched. The reinforced layer 742 may be etched to have a same planar shape as the third layer 741C.

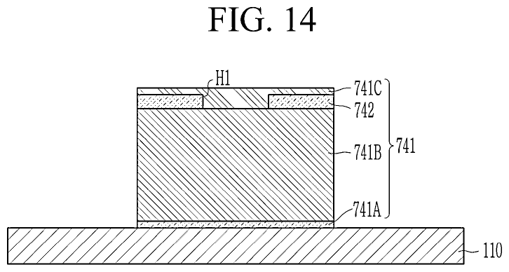

Referring to FIG. 14, the second layer 741B and the first layer 741A may be etched. The second layer 741B and the first layer 741A may be etched to have a same planar shape as the reinforced layer 742 and the third layer 741C.

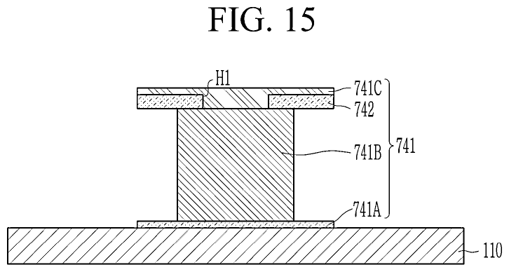

Referring to FIG. 15, the second layer 741B may be additionally etched to form an under-cut structure. Due to the additional etching of the second layer 741B, the second layer 741B may have a smaller width than the width of the third layer 741C in a direction perpendicular to the thickness direction of the substrate 110, and thus as shown in FIG. 3, the second electrode 270 and the common voltage line 741 may be in contact on a side of second layer 741B.

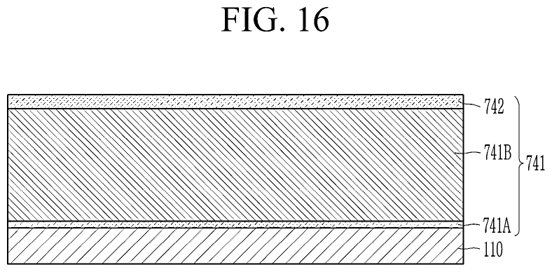

FIG. 16 to FIG. 20 are schematic cross-sectional views illustrating a manufacturing method of a common voltage line according to an embodiment. Referring to FIG. 16, a first layer 741A, a second layer 742B, and a reinforced layer 742 may be sequentially stacked on a substrate 110. The reinforced layer 742 may include an inorganic material or an organic material. For example, the reinforced layer 742 may include at least one of a silicon oxide (SiOₓ), a silicon nitride (SiNₓ), and a silicon oxynitride (SiOₓN_{y}). For example, the reinforced layer 742 may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer. For example, the reinforced layer 742 may include polyimide or an acrylic material. The first layer 741A and the second layer 741B may include at least one of Al, Cu, Ti, and alloys thereof.

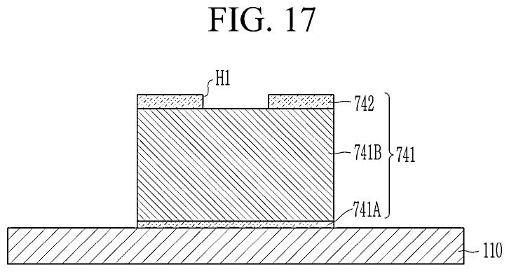

Referring to FIG. 17, an opening H1 may be formed in the reinforced layer 742. The second layer 741B may be partially exposed by the formation of the opening H1.

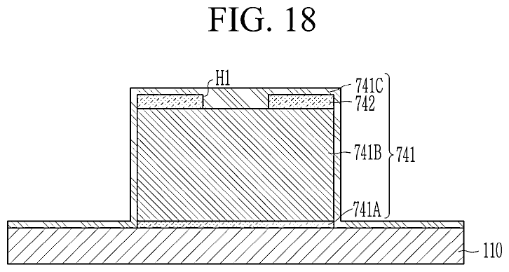

Referring to FIG. 18, a third layer 741C may be deposited. The third layer 741C may include at least one of Al, Cu, Ti, and alloys thereof. The third layer 741C may contact the second layer 741B in the opening H1.

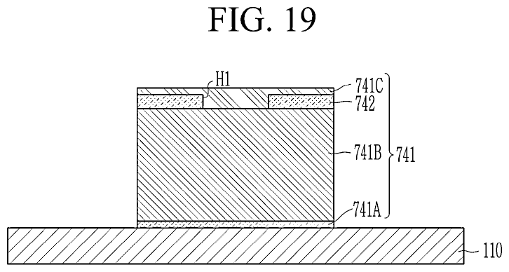

Referring to FIG. 19, the third layer 741C may be etched. The third layer 741C may have a same planar shape as the first layer 741A, the second layer 742B, and the reinforced layer 742.

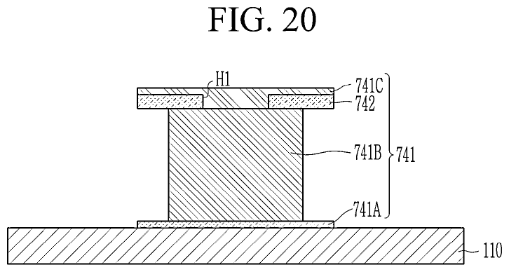

Referring to FIG. 20, the second layer 741B may be additionally etched to form an under-cut structure. Due to the additional etching of the second layer 741B, the second layer 741B may have a smaller width than the width of the third layer 741C, and thus as shown in FIG. 3, the second electrode 270 and the common voltage line 741 may be in contact with each other on a side of second layer 741B.

A pixel of the display device according to an embodiment is described with reference to accompanying drawings. The structure described below is only an example, and the disclosure is not limited thereto. For better comprehension and ease of description, the pixel in which the common voltage line 741 is positioned is described.

FIG. 21 is a schematic cross-sectional view of a pixel of a display device according to an embodiment. Referring to FIG. 21, the substrate SUB may be positioned. The substrate SUB may include at least one of polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. The substrate SUB may be a rigid substrate or a flexible substrate capable of bending, folding, rolling, etc. The substrate SUB may be single-layered or multi-layered. The substrate SUB may have a structure in which at least one base layer and at least one inorganic layer, including a polymer resin sequentially stacked, are alternately stacked each other.

A light blocking layer BML may be positioned on the substrate SUB. The light blocking layer BML may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), or metal oxides, and may have a single layer or multi-layered structure including the same.

A buffer layer BUF may be positioned on the light blocking layer BML. The buffer layer BUF may include a silicon oxide (SiOₓ), a silicon nitride (SiNₓ), a silicon oxynitride (SiOₓN_{y}), or amorphous silicon (Si).

The buffer layer BUF may include a first opening OP1 overlapping the light blocking layer BML in a plan view. In the first opening OP1, a source electrode SE may be connected to the light blocking layer BML.

The semiconductor layer ACT may include a channel region CA overlapping the gate electrode GE in a plan view, and a source region SA and a drain region DA positioned on each side of the channel region.

A gate insulating layer GI may be positioned on the semiconductor layer ACT. The gate insulating layer GI may include a silicon oxide (SiOₓ), a silicon nitride (SiNₓ), or a silicon oxynitride (SiOₓN_{y}), and may have a single layer or multi-layered structure including the same.

The gate insulating layer GI may be positioned to overlap the channel region CA of the semiconductor layer ACT in a plan view. A gate conductive layer including a gate electrode GE may be positioned on the gate insulating layer GI. The gate conductive layer may include molybdenum (Mo), aluminum (Al), copper (Cu), titanium (Ti), or a metal oxide, and may have a single layer or multi-layered structure including the same.

The gate electrode GE and the gate insulating layer GI may be formed in a same process, and have a same planar shape. The gate electrode GE may be positioned to overlap the semiconductor layer ACT in a direction perpendicular to the surface of the substrate SUB.

An interlayer insulating layer ILD may be positioned on the semiconductor layer ACT and the gate electrode GE. The interlayer insulating layer ILD may include a silicon oxide (SiOₓ), a silicon nitride (SiNₓ), and a silicon oxynitride (SiOₓN_{y}), and may have a single layer or multi-layered structure including the same. In case that the interlayer insulating layer ILD has a multi-layered structure including a silicon nitride and a silicon oxide, the layer including a silicon nitride may be positioned closer to the substrate SUB than the layer including a silicon oxide.

The interlayer insulating layer ILD may include a first opening OP1 overlapping the light blocking layer BML in a plan view, a second opening OP2 overlapping the source region SA of the semiconductor layer ACT in a plan view, and a third opening OP3 overlapping the drain region DA in a plan view.

On the interlayer insulating layer ILD, a data conductive layer including a source electrode SE and a drain electrode DE, and a common voltage line 741, may be positioned. The data conductive layer may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), or a metal oxide, and may be a single layer or multi-layered structure including the same. Referring to FIG. 21, the common voltage line 741 may have a 4-layered structure including a first layer 741A, a second layer 741B, a reinforced layer 742, and a third layer 741C. The first layer 741A, the second layer 741B, and the third layer 741C may include a metal. The reinforced layer 742 may be positioned between the second layer 741B and the third layer 741C, and may include a material that is more flexible than metal. For example, the reinforced layer 742 may include an inorganic material or an organic material. For example, the reinforced layer 742 may include at least one of a silicon oxide (SiOₓ), a silicon nitride (SiNₓ), and a silicon oxynitride (SiOₓN_{y}). For example, the reinforced layer 742 may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer. For example, the reinforced layer 742 may include polyimide or an acrylic material. The common voltage line 741 may have an under-cut structure in which the second layer 741B is more etched than the first layer 741A and the third layer 741C. The description of the common voltage line 741 is omitted as it is the same as described above.

The source electrode SE may contact the light blocking layer BML through the first opening OP1 and may contact the source region SA of the semiconductor layer ACT through the second opening OP2. The drain electrode DE may contact the drain region DA of the semiconductor layer ACT through the third opening OP3.

The source electrode SE, the drain electrode DE, and the common voltage line 741 may be formed in a same process and may have a same stacked structure. For example, the source electrode SE and the drain electrode DE may have the 4-layered structure including the first layer 741A, the second layer 741B, the reinforced layer 742, and the third layer 741C. The first layer 741A, the second layer 741B, and the third layer 741C may include a metal. The reinforced layer 742 may be positioned between the second layer 741B and the third layer 741C, and may include a material that is more flexible than metal. For example, the reinforced layer 742 may include an inorganic material or an organic material. For example, the reinforced layer 742 may include at least one of a silicon oxide (SiOₓ), a silicon nitride (SiNₓ), and a silicon oxynitride (SiOₓN_{y}). For example, the reinforced layer 742 may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer. For example, the reinforced layer 742 may include polyimide or an acrylic material. The reinforced layer 742 may include an opening H1, and the second layer 741B and the third layer 741C may be in contact with each other in the opening H1.

An insulating layer VIA may be positioned on the data conductive layer. The insulating layer VIA may include at least one of a general purpose polymer such as poly(methyl methacrylate) (PMMA) or polystyrene (PS), a polymer derivative having a phenolic group, an acryl-based polymer, an imide polymer, polyimide, and a siloxane polymer.

The insulating layer VIA may include a fourth opening OP4 overlapping the source electrode SE in a plan view and a fifth opening OP5 overlapping the common voltage line 741 in a plan view. A first electrode 191 may be positioned on the insulating layer VIA. A partition wall 350 may be positioned on the insulating layer VIA and the first electrode 191. The partition wall 350 may have an opening 355 overlapping the first electrode 191 in a plan view and an opening 356 overlapping the fifth opening OP5 in a plan view. An emission layer 360 may be positioned on the first electrode 191 and the partition wall 350. A second electrode 270 may be positioned on the emission layer 360. The first electrode 191, the emission layer 360, and the second electrode 270 may configure a light-emitting device LED.

As shown in B in FIG. 21, the second electrode 270 and the common voltage line 741 may be in contact with each other in the fifth opening OP5, thereby the common voltage may be transmitted to the second electrode 270. FIG. 21 shows, for better comprehension and ease of description, the thickness ratio in B is enlarged differently from other areas. As shown in FIG. 21, the common voltage line 741 may have a 4-layered structure including the first layer 741A, the second layer 741B, the reinforced layer 742, and the third layer 741C, and the flexible reinforced layer 742 may be positioned between the second layer 741B and the third layer 741C, thereby preventing the damage of the common voltage line 741 having the under-cut structure.

In the above, the embodiment in which the common voltage line 741 includes the reinforced layer 742, and the reinforced layer 742 includes the opening H1 is shown, but the disclosure is not limited thereto, and in an embodiment, the reinforced layer 742 of the common voltage line 741 may not include an opening.

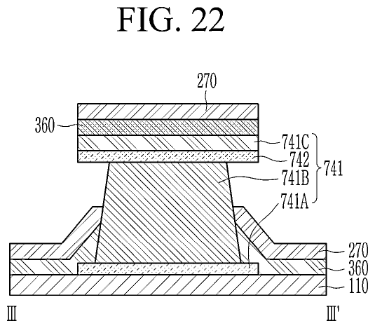

FIG. 22 is a schematic cross-sectional view taken along line III-III′ of FIG. 2, illustrating a configuration of a common voltage line contacting a second electrode according to an embodiment. Referring to FIG. 22, in the common voltage line 741 according to an embodiment, the reinforced layer 742 may not include an opening. Since the reinforced layer 742 does not include an opening, the third layer 741C and the second layer 741B may be insulated by the reinforced layer 742. However, as shown in FIG. 22, since the second electrode 270 contacts a side of the second layer 741B, the second electrode 270 may be electrically connected through the second layer 741B.

However, since it is essential that the third layer 741C and the second layer 741B of the source electrode SE and the drain electrode DE positioned on a same layer as the common voltage line 741 are electrically connected, the reinforced layer 742 of the source electrode SE and the drain electrode DE may include an opening H1.

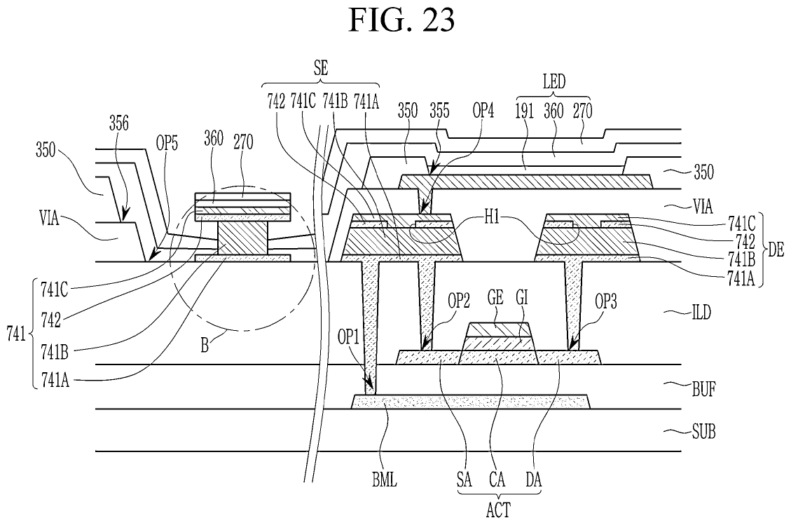

FIG. 23 is a schematic cross-sectional of a pixel of a display device according to an embodiment. The embodiment of FIG. 22 is the same as that of FIG. 21 except that the reinforced layer 742 of the common voltage line 741 does not include an opening. The description for the same constituent elements is omitted. Referring to FIG. 23, the reinforced layer 742 of the source electrode SE and the drain electrode DE positioned on a same layer as the common voltage line 741 may include an opening H1. Therefore, the source electrode SE and the drain electrode DE may have a conductive characteristic without being insulated internally.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display area and a non-display area;
an external common voltage line formed in the non-display area;
a common voltage line formed in the display area and connecting a portion and another portion of the external common voltage line;
a plurality of pixels positioned in the display area and including a first electrode and an emission layer; and
a second electrode positioned on the plurality of pixels, wherein
the common voltage line has a multi-layered structure including a first layer, a second layer, a third layer, and a reinforced layer,
the reinforce layer is positioned between the second layer and the third layer,
the first layer, the second layer, and the third layer include a metal, and
the reinforced layer includes an inorganic material or an organic material.

2. The display device of claim 1, wherein
the reinforced layer includes an opening, and
the second layer directly contacts the third layer in the opening.

3. The display device of claim 1, wherein the reinforced layer includes at least one of a silicon oxide (SiOₓ), a silicon nitride (SiNₓ), and a silicon oxynitride (SiOₓN_{y}).

4. The display device of claim 1, wherein the reinforced layer includes polyimide or an acrylic material.

5. The display device of claim 1, wherein
a thickness of the reinforced layer is in a range of about 20% to about 200% of a thickness of the third layer.

6. The display device of claim 5, wherein the thickness of the third layer is in a range of about 200 Å to about 1000 Å.

7. The display device of claim 1, wherein
the second layer has an under-cut structure, and
a width of the second layer is smaller than a width of the third layer and a width of the reinforced layer.

8. The display device of claim 1, wherein
the reinforced layer includes a first layer and a second layer,
the first layer of the reinforced layer includes an inorganic material, and
the second layer of the reinforced layer includes an organic material.

9. The display device of claim 2, wherein the reinforced layer includes multiple openings.

10. The display device of claim 1, wherein
the second electrode contacts a side of the second electrode.

11. The display device of claim 1, wherein
the first layer and the third layer include a same material, and
the first and third layers and the second layer include different materials.

12. The display device of claim 1, wherein the first layer to the third layer include different materials.

13. The display device of claim 1, further comprising:
a source electrode and a drain electrode positioned in the display area, wherein
the common voltage line, the source electrode, and the drain electrode are positioned on a same layer.

14. The display device of claim 1, wherein
the emission layer and the second electrode are sequentially positioned on the third layer of the common voltage line, and
the third layer of the common voltage line does not directly contact the second electrode.

15. A manufacturing method of a display device, comprising:
forming a first layer, a second layer, and a reinforced layer on a substrate;
forming a third layer on the reinforced layer;
etching the third layer, the reinforced layer, the second layer, and the first layer; and
additionally etching the second layer to form an under-cut structure in which a width of the second layer is smaller than a width of the third layer and a width of the reinforced layer, wherein
the first layer, the second layer, and the third layer include a metal, and
the reinforced layer includes an inorganic material or an organic material.

16. The manufacturing method of the display device of claim 15, further comprising:
forming an opening in the reinforced layer, wherein
the second layer directly contacts the third layer in the opening.

17. The manufacturing method of the display device of claim 15, wherein a thickness of the reinforced layer is in a range of about 20% to about 200% of a thickness of the third layer in a thickness direction of the substrate.

18. The manufacturing method of the display device of claim 15, wherein the reinforced layer includes at least one of a silicon oxide (SiOₓ), a silicon nitride (SiNₓ), a silicon oxynitride (SiOₓN_{y}), polyimide, and an acrylic material.

19. The manufacturing method of the display device of claim 15, wherein
the reinforced layer includes a first layer and a second layer,
the first layer of the reinforced layer includes an inorganic material, and
the second layer of the reinforced layer includes an organic material.

20. The manufacturing method of the display device of claim 16, wherein the forming of the opening includes forming multiple openings in the reinforced layer.
